(19) United States
(12) Patent Application Publication
(10) Pub. No.: US 2018/0190516 A1
(43) Pub. Date: Jul. 5, 2018

(54) COATING METHOD OF NON-NEWTONIAN FLUID MATERIAL AND COATING SYSTEM THEREOF

(71) Applicant: Industrial Technology Research Institute, Hsinchu (TW)

(72) Inventors: Yuh-Shyang Chen, Taipei City (TW); Te-Yi Chang, Taoyuan City (TW)

(21) Appl. No.: 15/786,508

(22) Filed: Oct. 17, 2017

(30) Foreign Application Priority Data
Dec. 30, 2016 (TW) 105144020

(51) Int. Cl. H01L 21/67; B01F 3/08; C08K 9/04; B41J 2/01; H01L 21/677

(52) U.S. Cl. CPC H01L 21/67017; B01F 3/0811; B01J 2219/00164; B41J 2/01; H01L 21/677; C08K 9/04

(57) ABSTRACT

A coating method of a non-Newtonian fluid material and a coating system thereof are provided. The coating method includes the following steps. An equation of shear rate and shear viscosity of the non-Newtonian fluid material represented by equation (1) is obtained:

$$η = {η}_{0} {\dot{γ}}^{( n - 1 )} , \qquad ( 1 )$$

wherein η is shear viscosity, η₀ is zero shear viscosity, \dot{γ} is shear rate, and n is power-law index. An initial gap between a coating apparatus and a substrate and a thickness of a film of the non-Newtonian fluid material to be formed are set. The non-Newtonian fluid material is coated on the substrate in a non-constant coating velocity manner using the coating apparatus. The shear viscosity of the non-Newtonian fluid material is obtained from equation (1) according to the coating velocity and thickness of the non-Newtonian fluid material. The gap between the coating apparatus and the substrate is adjusted according to the shear viscosity, coating velocity, and thickness.

### CROSS-REFERENCE TO RELATED APPLICATION

This application claims the priority benefit of Taiwan application serial no. 105144020, filed on Dec. 30, 2016. The entirety of the above-mentioned patent application is hereby incorporated by reference herein and made a part of this specification.

### TECHNICAL FIELD

The disclosure relates to a coating method and a coating system thereof, and relates to a coating method of a non-Newtonian fluid material and a coating system thereof.

### BACKGROUND

The manufacture of a functional thin film product via a wet coating process is a highly efficient and fast technique. A wet coating process is very competitive against a dry process such as PVD (physical vapor deposition) and CVD (chemical vapor deposition) in terms of cost and yield, and can be applied in the process of, for instance, a photoresist of a lithography process, the manufacture of a color filter via a dye pigment dispersion method, a liquid crystal display alignment film, and the low dielectric organic layer of an integrated circuit.

Former coating materials mostly have low viscosity, and in recent years, due to the rise of the flexible substrate, a high-viscosity fluid, i.e., non-Newtonian fluid, is also used as a coating material. However, the coating process of the non-Newtonian fluid has the issues of narrow coating process window, prone to film breakage, and poor film properties. Therefore, the research for a reliable coating method and coating system of a non-Newtonian fluid is still widely underway.

### SUMMARY

The disclosure provides a coating method of a non-Newtonian fluid material suitable for coating the non-Newtonian fluid material on a substrate using a coating apparatus. The coating method of the non-Newtonian fluid material includes the following steps. An equation of shear rate and shear viscosity of the non-Newtonian fluid material represented by equation (1) is obtained,

$$η = {η}_{0} {\dot{γ}}^{( n - 1 )} \qquad ( 1 )$$

wherein η is shear viscosity, η₀ is zero shear viscosity, \dot{y} is shear rate, and n is power-law index. An initial gap between a coating apparatus and a substrate and a thickness of a film of the non-Newtonian fluid material to be formed are set. The non-Newtonian fluid material is coated on the substrate in a non-constant coating velocity manner using the coating apparatus. The shear viscosity of the non-Newtonian fluid material is obtained from equation (1) according to the coating velocity and thickness of the non-Newtonian fluid material. The gap between the coating apparatus and the substrate is adjusted according to the shear viscosity, coating velocity, and thickness.

The disclosure provides a coating system of a non-Newtonian fluid material including a coating apparatus, a gap adjustment unit, a velocity adjustment unit, a coating material supply unit, and a control unit. The coating apparatus is used to coat the non-Newtonian fluid material on a substrate. The gap adjustment unit is connected to the coating apparatus to adjust the gap between the coating apparatus and the substrate. The velocity adjustment unit is connected to the coating apparatus to adjust the coating velocity of the non-Newtonian fluid material using the coating apparatus. The coating material supply unit is connected to the coating apparatus to supply the non-Newtonian fluid material to the coating apparatus. The control unit is connected to the velocity adjustment unit and the gap adjustment unit to control the velocity adjustment unit and to control the gap adjustment unit according to the value of the gap between the coating apparatus and the substrate obtained in the coating method of the non-Newtonian fluid material described above.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic diagram of a coating system of a non-Newtonian fluid material according to an embodiment of the disclosure.

FIG. 2 is a schematic diagram of a coating apparatus according to an embodiment of the disclosure.

FIG. 3 is a flowchart of a coating method according to an embodiment of the disclosure.

FIG. 4 is a graph of capillary number to dimensionless thickness according to an embodiment of the disclosure.

FIG. 5 is a graph of shear rate to shear viscosity according to experimental example 1 of the disclosure.

FIG. 6 is a graph of capillary number to dimensionless thickness according to experimental example 1 and comparative example 1-1 to comparative example 1-2 of the disclosure.

FIG. 7 is a graph of shear rate to shear viscosity according to experimental example 2 of the disclosure.

FIG. 8 is a graph of capillary number to dimensionless thickness according to experimental example 2 and comparative example 2-1 to comparative example 2-2 of the disclosure.

FIG. 9 is a graph of shear rate to shear viscosity according to experimental example 3 of the disclosure.

FIG. 10 is a graph of capillary number to dimensionless thickness according to experimental example 3 and comparative example 3-1 to comparative example 3-2 of the disclosure.

### DETAILED DESCRIPTION OF DISCLOSED EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

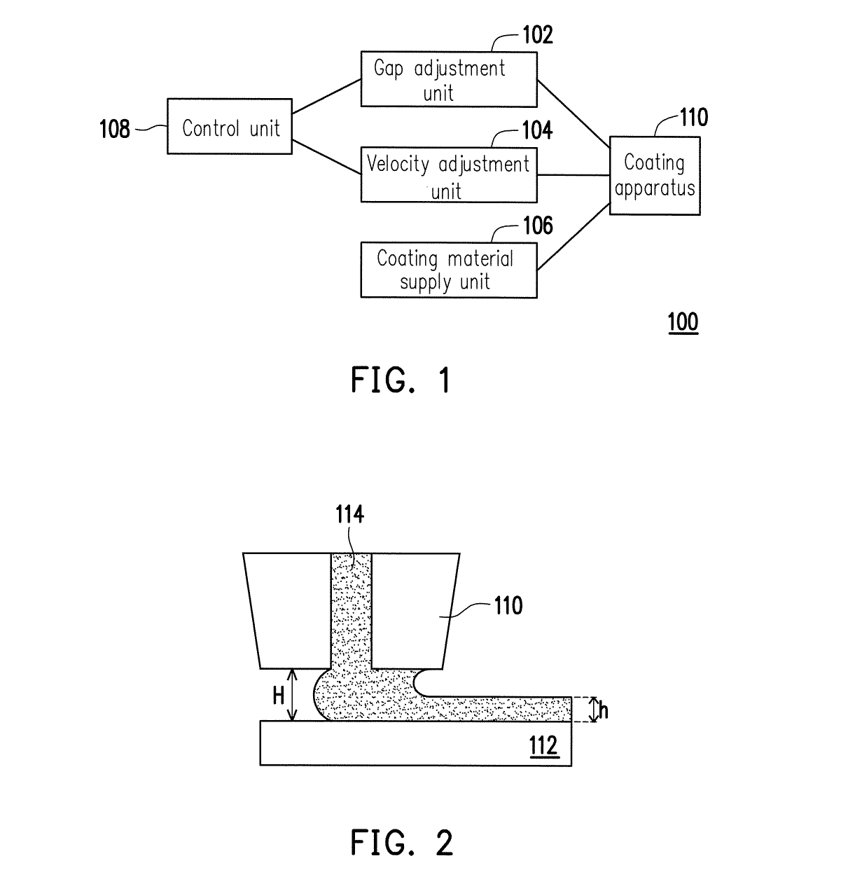

FIG. 1 is a schematic diagram of a coating system of a non-Newtonian fluid material according to an embodiment of the disclosure. FIG. 2 is a schematic diagram of a coating apparatus according to an embodiment of the disclosure.

Referring to both FIG. 1 and FIG. 2, a coating system 100 of a non-Newtonian fluid material includes a coating apparatus 110, a gap adjustment unit 102, a velocity adjustment unit 104, a coating material supply unit 106, and a control unit 108.

The coating apparatus 110 is used to coat a non-Newtonian fluid material 114 on a substrate 112. The coating apparatus 110 is, for instance, a slit coating apparatus. The gap adjustment unit 102 is connected to the coating apparatus 110 to adjust a gap H between the coating apparatus 110 and the substrate 112. The velocity adjustment unit 104 is connected to the coating apparatus 110 to adjust the coating velocity of the non-Newtonian fluid material 114 using the coating apparatus 110. The coating material supply unit 106 is connected to the coating apparatus 110 to supply the non-Newtonian fluid material 114 to the coating apparatus 110. The coating material supply unit 106 can include a quantitative motor and a quantitative syringe (not shown). The quantitative motor is connected to the quantitative syringe such that the quantitative syringe takes in the non-Newtonian fluid material 114 and provides the non-Newtonian fluid material 114 to the coating apparatus 110. The control unit 108 is connected to the velocity adjustment unit 104 and the gap adjustment unit 102 to control the velocity adjustment unit 104 and to control the gap adjustment unit 102 according to the value of the gap H obtained in the following coating method of the non-Newtonian fluid material.

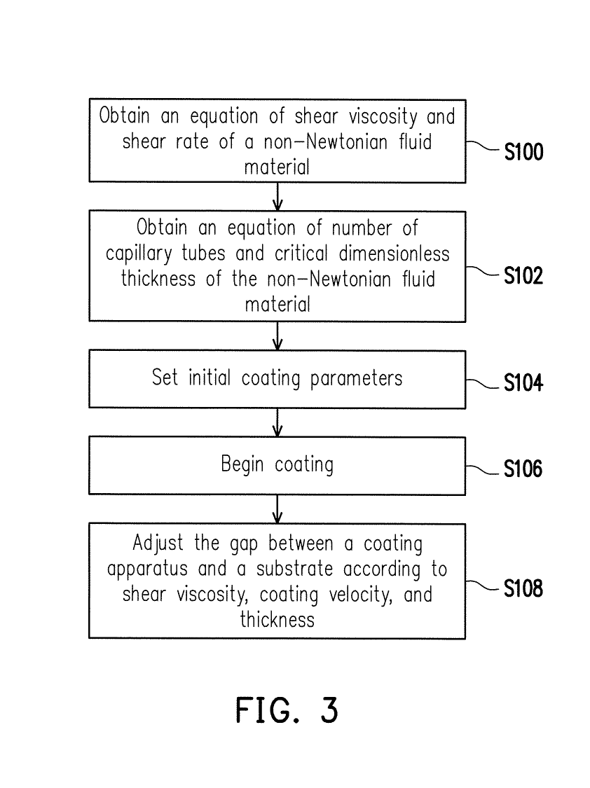

FIG. 3 is a flowchart of a coating method according to an embodiment of the disclosure. Please refer to all of FIG. 1 to FIG. 3. The disclosure provides a coating method of a non-Newtonian fluid material suitable for coating the non-Newtonian fluid material 114 on the substrate 112 using the coating system 100.

The non-Newtonian fluid material 114 includes a polymer, photoresist, or liquid crystal material. For instance, the polymer can include high-temperature polyimide (PI), the photoresist can include an acrylic photoresist coating material, and the liquid crystal material can include a polarized liquid crystal material (such as a polarized liquid crystal material made by OPTIVA). In an embodiment, the viscosity of the non-Newtonian fluid material 114 at 10° C. to 40° C. is, for instance, 50 cp to 6000 cp, and in particular, the viscosity at 20° C. to 30° C. is, for instance, 50 cp to 6000 cp.

The coating method of the non-Newtonian fluid material 114 includes the following steps.

In step S100, an equation of the shear viscosity and shear rate of the non-Newtonian fluid material 114 is obtained. The equation is as represented by equation (1) below:

$$η = {η}_{0} {\dot{γ}}^{( n - 1 )} \qquad ( 1 )$$

wherein η is shear viscosity, η₀ is zero shear viscosity, \dot{γ} is shear rate, and n is power-law index. Moreover, the shear rate \dot{γ} in equation (1) can be represented by equation (1-1) below:

$$\dot{γ} = \frac{U}{h} \qquad ( 1 \text{-} 1 )$$

wherein U is the coating velocity of the non-Newtonian fluid material 114 and h is the thickness of the film to be formed (such as a thickness h of the film to be formed shown in FIG. 2).

In equation (1), the zero shear viscosity is the shear viscosity of the non-Newtonian fluid material 114 when the shear rate approaches zero. Different non-Newtonian fluid materials have different power-law indexes that can describe the fluid behavior of the fluid material. In an embodiment, the graph of shear rate to shear viscosity of the non-Newtonian fluid material can be obtained using a rheometer or viscometer at a fixed temperature, and then the power-law index and zero shear viscosity of the non-Newtonian fluid material are obtained using a power regression method. It should be mentioned that, since the fluid material in the disclosure is a non-Newtonian fluid material, the power-law index is a value greater than 1 or less than 1.

Therefore, during the coating process of the non-Newtonian fluid material 114, the shear rate can be obtained by the thickness h of the film to be formed and the coating velocity of the non-Newtonian fluid material 114 at this velocity, and the shear viscosity at this velocity is obtained by the shear rate.

Next, in step S102, an equation of the capillary number and critical dimensionless thickness of the non-Newtonian fluid material 114 can be obtained. The equation is represented by equation (2a) and equation (2b) below:

when Ca<0.1, t₀=XCa^{Y} (2a)

when Ca≥0.1, t₀=Z (2b),

wherein X is a real number of 35 to 53, Y is a real number of 1.7 to 1.9, Z is a real number of 0.6 to 0.7, Ca is the capillary number, and t₀ is the critical dimensionless thickness. Moreover, the capillary number Ca in equation (2a) and equation (2b) can be represented by equation (2-1) below:

$$Ca = \frac{η}{σ} \times U \qquad ( 2 \text{-} 1 )$$

wherein σ is surface tension. Moreover, the critical dimensionless thickness t₀ in equation (2a) and equation (2b) can be represented by equation (2-2) below:

$${t}_{0} = \frac{h}{{H}_{0}} \qquad ( 2 \text{-} 2 )$$

wherein H₀ is the critical gap between the coating apparatus 110 and the substrate 112.

The critical dimensionless thickness and critical gap can be used to determine the quality of the film formed by coating the non-Newtonian fluid material 114 on the substrate 112, such as whether the issue of film breakage occurs, or the uniformity of the film thickness.

The capillary number and critical dimensionless thickness of the non-Newtonian fluid material 114 can be obtained by the coating velocity of the non-Newtonian fluid material 114, the shear viscosity of the non-Newtonian fluid material 114 at this velocity and the surface tension of the non-Newtonian fluid material 114 measured by a surface tension tester via equation (2a), equation (2b), and equation (2-1). Then, the critical gap corresponding to the coating velocity of the non-Newtonian fluid material 114 can be calculated from equation (2-2). In an embodiment, the different critical gaps corresponding to different coating velocities of the non-Newtonian fluid material 114 obtained from step S102 can be stored in the control unit 108.

Next, step S104 is performed to set the initial coating parameters. Specifically, in this step, the initial gap (not shown) between the coating apparatus 110 and the substrate 112 and the thickness h of the film to be formed are set. In an embodiment, the initial gap can be 2 to 4 times the thickness h of the film to be formed, and the thickness h of the film to be formed is, for instance, greater than or equal to 5 μm or between 10 μm and 1000 μm.

After the setting of the initial coating parameters is complete, step S106 is performed to coat. The velocity adjustment unit 104 is controlled via the control unit 108 in FIG. 1 to adjust the coating apparatus 110 so as to coat the non-Newtonian fluid material 114 on the substrate 112 in a non-constant velocity manner. The non-constant velocity manner includes constant acceleration, variable acceleration, constant deceleration, or variable deceleration. In an embodiment, the front end of the coating process can be constant acceleration or variable acceleration, and the back end of the coating process can be constant deceleration or variable deceleration, but the disclosure is not limited thereto, and those having ordinary skill in the art can adjust the coating velocity of the non-Newtonian fluid material 114 as needed.

Then, step S108 is performed, and the gap H between the coating apparatus 110 and the substrate 112 is adjusted according to the shear viscosity, coating velocity, and the thickness h of the film to be formed. Specifically, different coating velocities can cause the non-Newtonian fluid material 114 to have different shear viscosities and capillary number, and different capillary number correspond to different critical dimensionless thicknesses and different critical gaps. In other words, during the coating process of the non-Newtonian fluid material 114, the shear viscosity, capillary number, critical dimensionless thickness, and critical gap are all changed with different coating velocities. Moreover, the critical dimensionless thickness and critical gap are related to the quality of the film formed on the substrate 112 by the non-Newtonian fluid material 114. Therefore, in step S108, the gap H between the coating apparatus 110 and the substrate 112 can be adjusted with different coating velocities to make the gap H less than or equal to the critical gap corresponding to the coating velocity, and therefore the film-forming quality can be adjusted.

Specifically, referring to equation (1) and equation (1-1) in step S100, the corresponding shear viscosity of the non-Newtonian fluid material 114 can be obtained according to the coating velocity of the non-Newtonian fluid material 114 and the thickness h of the film to be formed. Next, referring to equation (2a), equation (2b), and equation (2-1) in step S102, the corresponding capillary number and critical dimensionless thickness of the non-Newtonian fluid material 114 can be obtained from the surface tension of the non-Newtonian fluid material 114 and the coating velocity of the non-Newtonian fluid material 114 and the corresponding shear viscosity thereof. Then, referring to equation (2-2) in step S102, the critical gap corresponding to the coating velocity of the non-Newtonian fluid material 114 can be obtained. Next, the gap H between the coating apparatus 110 and the substrate 112 is adjusted to make the gap H less than or equal to the critical gap to ensure the quality of the film. In an embodiment, the value of the critical gap corresponding to the coating velocity of the non-Newtonian fluid material 114 can be stored in the control unit 108 in step S102. Moreover, in step S108, the control unit 108 can be used to control the gap adjustment unit 102 to adjust the gap H between the coating apparatus 110 and the substrate 112 to make the gap H less than or equal to the critical gap.

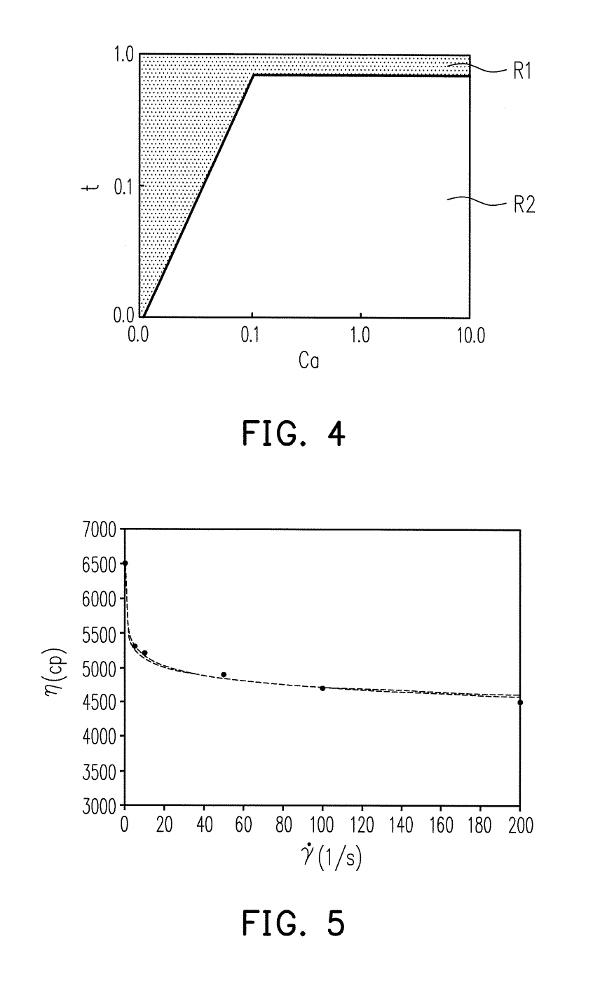

FIG. 4 is a graph of capillary number to dimensionless thickness according to an embodiment of the disclosure.

Referring to FIG. 4, the vertical axis of FIG. 4 is the dimensionless thickness which is the ratio of the thickness h of the film to be formed to the gap H during the actual coating process, and the horizontal axis of FIG. 4 is the capillary number of the non-Newtonian fluid material 114. It can be seen from FIG. 4 that, a film-forming region R1 and a non-film-forming region R2 are formed by the curves produced according to equation (2a) and equation (2b). Specifically, when the capillary number is the same and the dimensionless thickness is greater than or equal to the critical dimensionless thickness during the actual coating process, the non-Newtonian fluid material 114 can be successfully formed into a film on the substrate 112. Therefore, the region above the lines (including the lines) of equation (2a) and equation (2b) in FIG. 4 is the film-forming region R1. On the other hand, the region below the lines (excluding the lines) of equation (2a) and equation (2b) in FIG. 4 is the non-film-forming region R2. Therefore, it can be known from equation (2-2) that, when the dimensionless thickness during the actual coating process is less than the critical dimensionless thickness (the coating gap H is greater than the critical gap H₀), the non-Newtonian fluid material 114 is not readily formed into a film on the substrate 112, and the issue of film breakage readily occurs.

It can be known from the above that, when the dimensionless thickness is greater than or equal to the critical dimensionless thickness, coating should occur in the film-forming region R1 in FIG. 4. At this point, the gap H does not need to be adjusted. However, when the dimensionless thickness is less than the critical dimensionless thickness, coating should occur in the non-film-forming region R2 in FIG. 4. At this point, the gap adjustment unit 102 is controlled by the control unit 108 in FIG. 1, and the gap H between the coating apparatus 110 and the substrate 112 is adjusted to make the gap H less than or equal to the critical gap. The gap H is adjusted according to the critical gap obtained from equation (2-2) to be less than or equal to the critical gap to adjust the dimensionless thickness to be greater than or equal to the critical dimensionless thickness. That it, the adjusted coating occurs in the film-forming region R1 in FIG. 4.

Therefore, during the coating process, when the non-Newtonian fluid material is coated on the substrate (such as the front end and back end of the coating process) in a non-constant velocity manner, by adjusting the gap between the coating apparatus and the substrate during the coating process, the coating of the non-Newtonian fluid material can be ensured to be kept in the film-forming region R1 in FIG. 4, and therefore good film thickness uniformity can be obtained such that the issue of film breakage does not readily occur. Moreover, the error tolerance of the gap during the coating process can be further increased, and therefore the process window can be increased.

Moreover, since the coating system of the non-Newtonian fluid material of the disclosure controls the gap between the coating apparatus and the substrate via the coating method of the non-Newtonian fluid material described above, performing a coating process using the coating system of the non-Newtonian fluid material of the disclosure can have the advantages of good film-forming quality and high process window.

Experiments are provided below to verify the efficacy of the disclosure. However, the disclosure is not limited to the following content.

### Experimental Example 1

FIG. 5 is a graph of shear rate to shear viscosity according to experimental example 1 of the disclosure.

Referring to FIG. 5, in the present experimental embodiment, the non-Newtonian fluid material is high-temperature polyimide (PI) which is a high-viscosity material. In the present experimental embodiment, shear viscosities of the high-temperature polyimide at room temperature (such as 23° C.±10) corresponding to different shear rates can be obtained using a viscometer (such as a Brookfield DV II+ viscometer) as shown in FIG. 5. Then, the zero shear viscosity and power-law index of the high-temperature polyimide at room temperature can be obtained via a regression method according to the data of FIG. 5, which are respectively 5564.3 cp and 0.964. In step S100, the zero shear viscosity and power-law index can be entered into equation (1) to obtain the relationship of shear viscosity and shear rate of the polyimide. When shear viscosities of the high-temperature polyimide corresponding to different shear rates are obtained using a viscometer, the different shear rates are directly proportional to different flow velocities, and the flow velocities can be regarded as different coating velocities in subsequent processes.

According to step S102, the surface tension measured using a surface tension tester (such as KRUSS) and different coating velocities and corresponding shear viscosities thereof of the high-temperature polyimide can be entered into equation (2a), equation (2b), and equation (2-1) to obtain critical dimensionless thicknesses corresponding to different coating viscosities. Then, critical gaps corresponding to different coating velocities can be obtained from equation (2-2).

Next, step S104 is performed. In the present experimental example, the gap (i.e., initial gap) between the coating apparatus and the substrate before the start of coating is set to 350 μm, and the thickness h of the film to be formed is set to 144 μm. Then, step S106 is performed to begin coating. In the present experimental example, the coating velocity of the polyimide is constant acceleration. Specifically, the coating velocity is 0 mm/s at 0 seconds, and the coating velocity is increased to 5 mm/s until 1 second at a constant acceleration of 5 mm/s². Then, step S108 is performed to adjust the gap H via the shear viscosity, coating velocity, and the thickness h of the film to be formed to make the gap H less than or equal to the critical gap obtained in step S102. The parameters above are as shown in Table 1 below, wherein the gaps in Table 1 refer to the gaps adjusted in step S108.

TABLE 1

| | | Coating | Coating | Shear | | | |
|---|---|---|---|---|---|---|---|
| Time | Acceleration | velocity | distance | viscosity | Capillary | Dimensionless | (Gap) |
| (s) | (mm/s²) | (mm/s ) | (mm) | (cp) | number | thickness | (μm) |
| 0 | 0 | 0 | 0 | 5564.3 | 0 | 0.41 | 350 |
| 0.05 | 5 | 0.25 | 0.00625 | 5455 | 0.03 | 0.41 | 350 |
| 0.10 | 5 | 0.5 | 0.025 | 5320 | 0.05 | 0.53 | 270 |
| 0.15 | 5 | 0.75 | 0.5625 | 5243 | 0.08 | 0.81 | 178 |
| 0.20 | 5 | 1 | 0.1 | 5189 | 0.1 | 0.81 | 178 |
| 1 | 5 | 5 | 2.5 | 4897 | 0.49 | 0.81 | 178 |

### Comparative Example 1-1

The difference of comparative example 1-1 and experimental example 1 is only in that in comparative example 1-1, the gap is not adjusted according to the method of step S100 to step S108, and the gap of comparative example 1-1 is fixed at 180 μm and the other parameters are all the same as experimental example 1. The parameters of comparative example 1-1 are as shown in Table 2 below, wherein the gaps in Table 2 are not adjusted during the coating process.

TABLE 2

| | | Coating | Coating | Shear | | | |
|---|---|---|---|---|---|---|---|
| Time | Acceleration | velocity | distance | viscosity | Capillary | Dimensionless | Gap |
| (s) | (mm/s²) | (mm/s) | (mm) | (cp) | number | thickness | (μm) |
| 0 | 0 | 0 | 0 | 5564.3 | 0 | 0.8 | 180 |
| 0.05 | 5 | 0.25 | 0.00625 | 5455 | 0.03 | 0.8 | 180 |
| 0.10 | 5 | 0.50 | 0.025 | 5320 | 0.05 | 0.8 | 180 |
| 0.15 | 5 | 0.75 | 0.5625 | 5243 | 0.08 | 0.8 | 180 |
| 0.2 | 5 | 1 | 0.1 | 5189 | 0.1 | 0.8 | 180 |
| 1 | 5 | 5 | 2.5 | 4897 | 0.5 | 0.8 | 180 |

### Comparative Example 1-2

The difference of comparative example 1-2 and experimental example 1 is only in that in comparative example 1-2, the gap is not adjusted according to the method of step S100 to step S108, and the gap in comparative example 1-2 is fixed at 300 μm and the other parameters are all the same as experimental example 1. The parameters of comparative example 1-2 are as shown in Table 3 below, wherein the gaps in Table 3 are not adjusted during the coating process.

TABLE 3

| | | Coating | Coating | Shear | | | |
|---|---|---|---|---|---|---|---|
| Time | Acceleration | velocity | distance | viscosity | Capillary | Dimensionless | (Gap) |
| (s) | (mm/s²) | (mm/s ) | (mm) | (cp) | number | thickness | (μm) |
| 0 | 0 | 0 | 0 | 5564.3 | 0 | 0.48 | 300 |
| 0.05 | 5 | 0.25 | 0.00625 | 5455 | 0.03 | 0.48 | 300 |
| 0.10 | 5 | 0.50 | 0.025 | 5320 | 0.05 | 0.48 | 300 |
| 0.15 | 5 | 0.75 | 0.5625 | 5243 | 0.08 | 0.48 | 300 |
| 0.2 | 5 | 1 | 0.1 | 5189 | 0.1 | 0.48 | 300 |
| 1 | 5 | 5 | 2.5 | 4897 | 0.5 | 0.48 | 300 |

### Comparison of Experimental Example 1, Comparative Example 1-1, and Comparative Example 1-2

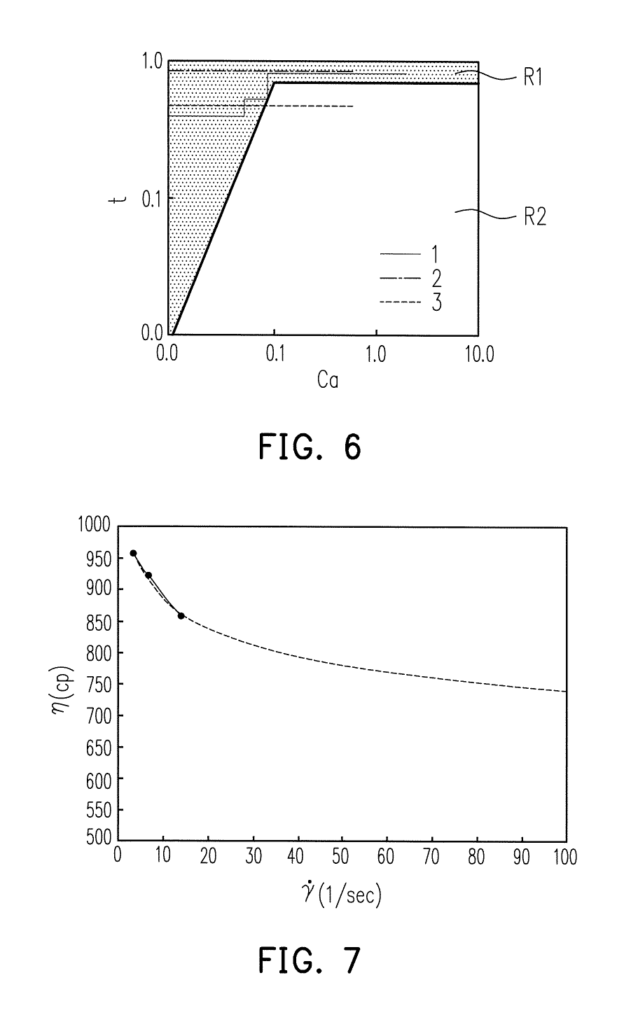

FIG. 6 is a graph of capillary number to dimensionless thickness according to experimental example 1 and comparative example 1-1 to comparative example 1-2 of the disclosure.

Referring to FIG. 6, as shown in line 1, in experimental example 1, the gap is adjusted dynamically, such that the coating of experimental example 1 is kept in the film-forming region R1. As shown by line 2, to keep the coating in comparative example 1-1 in the film-forming region R1, in comparative example 1-1, coating is performed at a lower and fixed gap. Although the coating of the polyimide can be within the film-forming region R1, the error tolerance for the control of the gap at this point is less, that is, a slight variation to the gap results in the coating to occur in the non-film-forming region R2. Moreover, a smaller gap more readily causes the issue of ink stains to the coating apparatus during the coating process. As shown by line 3, the gap of comparative example 1-2 is not adjusted during the coating process. Although the coating of the polyimide can be within the film-forming region R1 in the front end of the coating process, the coating of the polyimide is in the non-film-forming region R2 in the back end of the coating process. That is, the polyimide cannot readily form a film on the substrate such that the issue of film breakage occurs.

Based on the above, experimental example 1 can have the advantages of greater error tolerance for the control of the gap, reducing ink stains to the coating apparatus, and keeping the non-Newtonian fluid material in the film-forming region R1 during the coating process.

### Experimental Example 2

FIG. 7 is a graph of shear rate to shear viscosity according to experimental example 2 of the disclosure.

Referring to FIG. 7, experimental example 2 is only different from experimental example 1 in the following manner, and the other steps are all the same as experimental example 1. In experimental example 2, coating is performed using a thick film photoresist material such as an acrylic photoresist material. The thick film photoresist material is a medium viscosity material. At room temperature (such as 23±10° C.), the thick film photoresist has a zero shear viscosity of 1059.1 cp, a power-law index of 0.922, and a surface tension of 37 dyne/cm. In the present embodiment, the zero shear viscosity and power-law index can be measured by a viscometer (Brookfield DV II+ viscometer), and the surface tension can be measured by a surface tension tester (KRUSS). Moreover, the coating velocity is 0 mm/s at 0 seconds, and the coating velocity is increased to 10 mm/s until 1 second at a constant acceleration of 10 mm/s². In the present experimental example, the initial gap is set to 150 μm, and the thickness h of the film to be formed is set to 40 μm. The parameters of experimental example 2 are as shown in Table 4 below, wherein the gaps in Table 4 refer to the gaps adjusted in step S108.

TABLE 4

| | | Coating | Coating | Shear | | | |
|---|---|---|---|---|---|---|---|
| Time | Acceleration | velocity | distance | viscosity | Capillary | Dimensionless | (Gap) |
| (s) | (mm/s²) | (mm/s ) | (mm) | (cp) | number | thickness | (μm) |
| 0 | 0 | 0 | 0 | 1059.1 | 0 | 0.27 | 150 |
| 0.05 | 10 | 0.5 | 0.0125 | 869.7 | 0.01 | 0.27 | 150 |
| 0.3 | 10 | 3 | 1.5 | 756.3 | 0.06 | 0.34 | 119 |
| 0.35 | 10 | 3.5 | 1.75 | 747.2 | 0.07 | 0.44 | 91 |
| 0.4 | 10 | 4 | 2 | 739.5 | 0.08 | 0.55 | 73 |
| 0.45 | 10 | 4.5 | 2.25 | 732.7 | 0.09 | 0.68 | 59 |
| 0.5 | 10 | 5 | 2.5 | 726.7 | 0.1 | 0.82 | 49 |
| 1 | 10 | 10 | 50 | 688.5 | 0.19 | 0.82 | 49 |

### Comparative Example 2-1

The difference of comparative example 2-1 and experimental example 2 is only in that in comparative example 2-1, the gap is not adjusted during the coating process according to the method above, and the gap (fixed) of comparative example 2-1 is 50 μm and the other parameters are all the same as experimental example 2. The parameters of comparative example 2-1 are as shown in Table 5 below, wherein the gaps in Table 5 are not adjusted during the coating process.

TABLE 5

| | | Coating | Coating | Shear | | | |
|---|---|---|---|---|---|---|---|
| Time | Acceleration | velocity | distance | viscosity | Capillary | Dimensionless | (Gap) |
| (s) | (mm/s²) | (mm/s ) | (mm) | (cp) | number | thickness | (μm) |
| 0 | 0 | 0 | 0 | 1059.1 | 0 | 0.8 | 50 |
| 0.05 | 10 | 0.5 | 0.0125 | 869.7 | 0.01 | 0.8 | 50 |
| 0.3 | 10 | 3 | 1.5 | 756.3 | 0.06 | 0.8 | 50 |
| 0.35 | 10 | 3.5 | 1.75 | 747.2 | 0.07 | 0.8 | 50 |
| 0.4 | 10 | 4 | 2 | 739.5 | 0.08 | 0.8 | 50 |
| 0.45 | 10 | 4.5 | 2.25 | 732.7 | 0.09 | 0.8 | 50 |
| 0.5 | 10 | 5 | 2.5 | 726.7 | 0.1 | 0.8 | 50 |
| 1 | 10 | 10 | 50 | 688.5 | 0.19 | 0.8 | 50 |

### Comparative Example 2-2

The difference of comparative example 2-2 and experimental example 2 is only in that in comparative example 2-2, the gap is not adjusted during the coating process according to the method above, and the gap (fixed) of comparative example 2-2 is 130 μm and the other parameters are all the same as experimental example 2. The parameters of comparative example 2-2 are as shown in Table 6 below, wherein the gaps in Table 6 are not adjusted during the coating process.

TABLE 6

| | | Coating | Coating | Shear | | | |
|---|---|---|---|---|---|---|---|
| Time | Acceleration | velocity | distance | viscosity | Capillary | Dimensionless | (Gap) |
| (s) | (mm/s²) | (mm/s ) | (mm) | (cp) | number | thickness | (μm) |
| 0 | 0 | 0 | 0 | 1059.1 | 0 | 0.31 | 130 |
| 0.05 | 10 | 0.5 | 0.0125 | 869.7 | 0.01 | 0.31 | 130 |
| 0.3 | 10 | 3 | 1.5 | 756.3 | 0.06 | 0.31 | 130 |
| 0.35 | 10 | 3.5 | 1.75 | 747.2 | 0.07 | 0.31 | 130 |
| 0.4 | 10 | 4 | 2 | 739.5 | 0.08 | 0.31 | 130 |
| 0.45 | 10 | 4.5 | 2.25 | 732.7 | 0.09 | 0.31 | 130 |
| 0.5 | 10 | 5 | 2.5 | 726.7 | 0.1 | 0.31 | 130 |
| 1 | 10 | 10 | 50 | 688.5 | 0.2 | 0.31 | 130 |

### Comparison of Experimental Example 2, Comparative Example 2-1, and Comparative Example 2-2

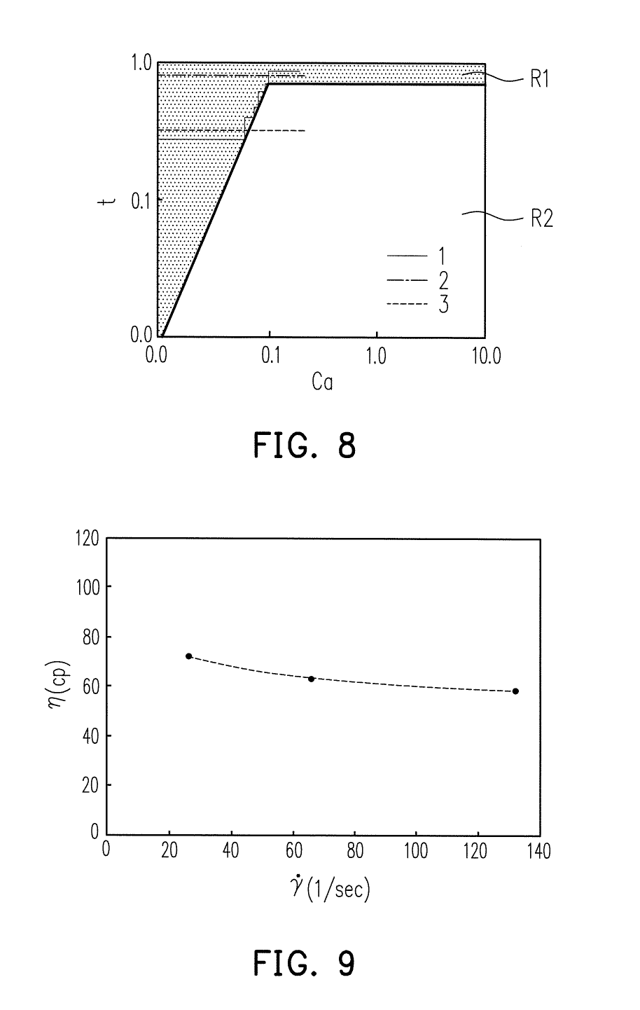

FIG. 8 is a graph of capillary number to dimensionless thickness according to experimental example 2 and comparative example 2-1 to comparative example 2-2 of the disclosure.

Referring to FIG. 8, line 1, line 2, and line 3 in FIG. 8 represent the dimensionless thicknesses of experimental example 2, comparative example 2-1, and comparative example 2-2 in that order. Similar to the comparison of experimental example 1, comparative example 1-1 and comparative example 1-2, experimental example 2 can have the advantages of greater error tolerance for the control of the gap, reducing ink stains to the coating apparatus, and keeping the non-Newtonian fluid material in the film-forming region R1 during the coating process.

### Experimental Example 3

FIG. 9 is a graph of shear rate to shear viscosity according to experimental example 3 of the disclosure.

Referring to FIG. 9, experimental example 3 is only different from experimental example 1 in the following manner, and the other steps are all the same as experimental example 1. In experimental example 3, coating is performed using a polarized liquid crystal material (made by OPTIVA), which is a material having lower viscosity. At room temperature (such as 23° C.±10° C.), the polarized liquid crystal material has a zero shear viscosity of 111.65 cp, a power-law index of 0.865, and a surface tension of 32 dyne/cm. In the present embodiment, the zero shear viscosity and power-law index can be measured by a viscometer (Brookfield DV II+ viscometer), and the surface tension can be measured by a surface tension tester (KRUSS). Moreover, the coating velocity is 0 mm/s at 0 seconds, and the coating velocity is increased to 100 mm/s until 1 second at a constant acceleration of 100 mm/s². In the present experimental example, the initial gap is set to 15 μm, and the thickness h of the film to be formed is set to 5 μm. The parameters of experimental example 3 are as shown in Table 7 below, wherein the gaps in Table 7 refer to the gaps adjusted in step S108.

TABLE 7

| | | Coating | Coating | Shear | | | |
|---|---|---|---|---|---|---|---|
| Time | Acceleration | velocity | distance | viscosity | Capillary | Dimensionless | (Gap) |
| (s) | (mm/s²) | (mm/s ) | (mm) | (cp) | number | thickness | (μm) |
| 0 | 0 | 0 | 0 | 111.7 | 0 | 0.33 | 15 |
| 0.6 | 100 | 60 | 18 | 31.42 | 0.059 | 0.33 | 15 |
| 0.65 | 100 | 65 | 21.125 | 32 | 0.063 | 0.36 | 14 |
| 0.7 | 100 | 70 | 24.5 | 31.08 | 0.067 | 0.42 | 12 |
| 0.75 | 100 | 75 | 28.125 | 30.77 | 0.071 | 0.45 | 11 |
| 0.8 | 100 | 80 | 32 | 30.49 | 0.076 | 0.5 | 10 |
| 0.85 | 100 | 85 | 36.125 | 30.22 | 0.08 | 0.56 | 9 |
| 0.9 | 100 | 90 | 40.5 | 29.97 | 0.084 | 0.63 | 8 |
| 0.95 | 100 | 95 | 45.125 | 29.74 | 0.088 | 0.71 | 7 |
| 1 | 100 | 100 | 50 | 29.53 | 0.092 | 0.83 | 6 |

### Comparative Example 3-1

The difference of comparative example 3-1 and experimental example 3 is only in that in comparative example 3-1, the gap is not adjusted during the coating process according to the method above, and the gap (fixed) of comparative example 3-1 is 6 μm and the other parameters are all the same as experimental example 3. The parameters of comparative example 3-1 are as shown in Table 8 below, wherein the gaps in Table 8 are not adjusted during the coating process.

TABLE 8

| | | Coating | Coating | Shear | | | |
|---|---|---|---|---|---|---|---|
| Time | Acceleration | velocity | distance | viscosity | Capillary | Dimensionless | (Gap) |
| (s) | (mm/s²) | (mm/s ) | (mm) | (cp) | number | thickness | (μm) |
| 0 | 0 | 0 | 0 | 111.7 | 0 | 0.83 | 6 |
| 0.6 | 100 | 60 | 18 | 31.42 | 0.059 | 0.83 | 6 |
| 0.65 | 100 | 65 | 21.125 | 32 | 0.063 | 0.83 | 6 |
| 0.7 | 100 | 70 | 24.5 | 31.08 | 0.067 | 0.83 | 6 |
| 0.75 | 100 | 75 | 28.125 | 30.77 | 0.071 | 0.83 | 6 |
| 0.8 | 100 | 80 | 32 | 30.49 | 0.076 | 0.83 | 6 |
| 0.85 | 100 | 85 | 36.125 | 30.22 | 0.08 | 0.83 | 6 |
| 0.9 | 100 | 90 | 40.5 | 29.97 | 0.084 | 0.83 | 6 |
| 0.95 | 100 | 95 | 45.125 | 29.74 | 0.088 | 0.83 | 6 |
| 1 | 100 | 100 | 50 | 29.53 | 0.092 | 0.83 | 6 |

### Comparative Example 3-2

The difference of comparative example 3-2 and experimental example 3 is only in that in comparative example 3-2, the gap is not adjusted during the coating process according to the method above, and the gap (fixed) of comparative example 3-2 is 10 μm and the other parameters are all the same as experimental example 3. The parameters of comparative example 3-2 are as shown in Table 9 below, wherein the gaps in Table 9 are not adjusted during the coating process.

TABLE 9

| | | Coating | Coating | Shear | | | |
|---|---|---|---|---|---|---|---|
| Time | Acceleration | velocity | distance | viscosity | Capillary | Dimensionless | (Gap) |
| (s) | (mm/s²) | (mm/s ) | (mm) | (cp) | number | thickness | (μm) |
| 0 | 0 | 0 | 0 | 111.7 | 0 | 0.5 | 10 |
| 0.6 | 100 | 60 | 18 | 31.42 | 0.059 | 0.5 | 10 |
| 0.65 | 100 | 65 | 21.125 | 32 | 0.063 | 0.5 | 10 |
| 0.7 | 100 | 70 | 24.5 | 31.08 | 0.067 | 0.5 | 10 |
| 0.75 | 100 | 75 | 28.125 | 30.77 | 0.071 | 0.5 | 10 |
| 0.8 | 100 | 80 | 32 | 30.49 | 0.076 | 0.5 | 10 |
| 0.85 | 100 | 85 | 36.125 | 30.22 | 0.08 | 0.5 | 10 |
| 0.9 | 100 | 90 | 40.5 | 29.97 | 0.084 | 0.5 | 10 |
| 0.95 | 100 | 95 | 45.125 | 29.74 | 0.088 | 0.5 | 10 |
| 1 | 100 | 100 | 50 | 29.53 | 0.23 | 0.5 | 10 |

### Comparison of Experimental Example 3, Comparative Example 3-1, and Comparative Example 3-2

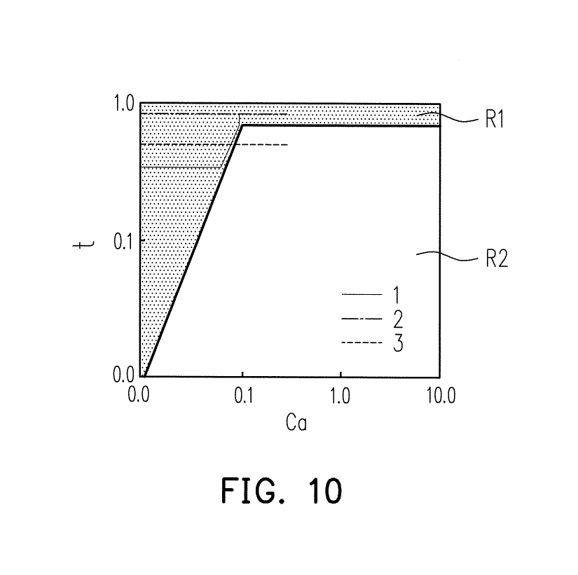

FIG. 10 is a graph of capillary number to dimensionless thickness according to experimental example 3 and comparative example 3-1 to comparative example 3-2 of the disclosure.

Referring to FIG. 10, line 1, line 2, and line 3 in FIG. 10 represent the dimensionless thicknesses of experimental example 3, comparative example 3-1, and comparative example 3-2 in that order. Similar to the comparison of experimental example 1, comparative example 1-1 and comparative example 1-2, experimental example 3 can have the advantages of greater error tolerance for the control of the gap, reducing ink stains to the coating apparatus, and keeping the non-Newtonian fluid material in the film-forming region R1 during the coating process.

Based on the above, in the disclosure, a thin film having uniform film thickness can be formed when the non-Newtonian fluid material is coated on the substrate in a non-constant velocity manner by adjusting the gap between the coating apparatus and the substrate during the coating process, and the issue of film breakage does not readily occur. Moreover, the disclosure can further increase the error tolerance of the gap between the coating apparatus and the substrate in the coating process, and therefore the process window can be increased.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A coating method of a non-Newtonian fluid material suitable for coating the non-Newtonian fluid material on a substrate using a coating apparatus, the coating method of the non-Newtonian fluid material comprising:
obtaining an equation of a shear rate and a shear viscosity of the non-Newtonian fluid material represented by equation (1),
$$η = {η}_{0} {\dot{γ}}^{( n - 1 )} , \qquad ( 1 )$$
wherein η is a shear viscosity, η₀ is a zero shear viscosity, \dot{γ} is a shear rate, and n is a power-law index;
setting an initial gap between the coating apparatus and the substrate and a thickness of a film of the non-Newtonian fluid material to be formed;
coating the non-Newtonian fluid material on the substrate in a non-constant coating velocity manner using the coating apparatus;
obtaining a shear viscosity of the non-Newtonian fluid material via equation (1) according to the coating velocity of the non-Newtonian fluid material and the thickness; and
adjusting a gap between the coating apparatus and the substrate according to the shear viscosity, the coating velocity, and the thickness.

2. The coating method of the non-Newtonian fluid material of claim 1, further comprising, after the step of obtaining the equation of the shear rate and the shear viscosity of the non-Newtonian fluid material and before the step of adjusting the gap between the coating apparatus and the substrate:
obtaining an equation of a capillary number and a critical dimensionless thickness of the non-Newtonian fluid material, wherein the equation is represented by equation (2a), equation (2b), equation (2-1), and equation (2-2):
when Ca<0.1, t₀=XCa^{Y} (2a)
when Ca≥0.1, t₀=Z (2b)
wherein X is a real number of 35 to 53, Y is a real number of 1.7 to 1.9, Z is a real number of 0.6 to 0.7, Ca is the capillary number, and t₀ is the critical dimensionless thickness,
and wherein the capillary number is represented by equation (2-1) below:
$$Ca = \frac{η}{σ} \times U \qquad ( 2 \text{-} 1 )$$
wherein Ca is the capillary number, σ is a surface tension, and U is the coating velocity,
and wherein the critical dimensionless thickness is represented by equation (2-2) below:
$${t}_{0} = \frac{h}{{H}_{0}} \qquad ( 2 \text{-} 2 )$$
wherein h is the thickness and H₀ is the critical gap, and the gap between the coating apparatus and the substrate is adjusted to be less than or equal to the critical gap in the step of adjusting the gap between the coating apparatus and the substrate.

3. The coating method of the non-Newtonian fluid material of claim 1, wherein a viscosity of the non-Newtonian fluid material is 50 cp to 6000 cp at 10° C. to 40° C.

4. The coating method of the non-Newtonian fluid material of claim 1, wherein a viscosity of the non-Newtonian fluid material is 50 cp to 6000 cp at 20° C. to 30° C.

5. The coating method of the non-Newtonian fluid material of claim 1, wherein the initial gap is 2 to 4 times the thickness.

6. The coating method of the non-Newtonian fluid material of claim 1, wherein the non-Newtonian fluid material comprises a polymer, a photoresist, or a liquid crystal material.

7. The coating method of the non-Newtonian fluid material of claim 1, wherein the thickness is greater than or equal to 5 μm.

8. The coating method of the non-Newtonian fluid material of claim 1, wherein the coating velocity comprises constant acceleration, variable acceleration, constant deceleration, or variable deceleration.

9. A coating system of a non-Newtonian fluid material, comprising:
a coating apparatus for coating the non-Newtonian fluid material on a substrate;
a gap adjustment unit connected to the coating apparatus to adjust a gap between the coating apparatus and the substrate;
a velocity adjustment unit connected to the coating apparatus to adjust a coating velocity of the non-Newtonian fluid material using the coating apparatus;
a coating material supply unit connected to the coating apparatus to supply the non-Newtonian fluid material to the coating apparatus; and
a control unit connected to the velocity adjustment unit and the gap adjustment unit to control the velocity adjustment unit and control the gap adjustment unit according to a value of the gap between the coating apparatus and the substrate obtained according to the coating method of the non-Newtonian fluid material of claim 1.

10. The coating system of the non-Newtonian fluid material of claim 9, wherein the coating material supply unit comprises a quantitative motor and a quantitative syringe.
